(19) United States
(12) Patent Application Publication
(10) Pub. No.: US 2025/0020864 A1
(43) Pub. Date: Jan. 16, 2025

(54) Passive On-Chip Optical Long-Pass Filter

(71) Applicant: The Hong Kong University of Science and Technology, Hong Kong (CN)

(72) Inventors: Jiayang LI, Hong Kong (CN); Wing-On POON, Hong Kong (CN)

(21) Appl. No.: 18/754,329

(22) Filed: Jun. 26, 2024

Related U.S. Application Data
(60) Provisional application No. 63/513,349, filed on Jul. 12, 2023.

(51) Int. Cl. G02B 6/122; G02B 6/12; G02B 6/125; H01L 31/0232

(52) U.S. Cl. CPC G02B 6/1225; G02B 6/125; H01L 31/0232; G02B 2006/12061; G02B 2006/12097; G02B 2006/12109; G02B 2006/12126

(57) ABSTRACT

A passive on-chip optical long-pass filter for removing residual pump photons at short wavelengths after nonlinear generation of photons. A thin layer (<100 nm) of amorphous or poly-crystalline silicon is deposited onto a section of a waveguide to absorb light with a wavelength shorter than the silicon bandgap wavelength of ˜1.1 μm, while the nonlinearly generated light in longer wavelengths than the silicon bandgap wavelength propagates in the waveguide with a negligible absorption loss. The filter is applicable to attain an on-chip optical pump light rejection ratio exceeding 120 dB for nonlinear and quantum photonic chips. The filter is conceptually simple to design and can be fabricated by a CMOS process with potentially a high wafer-level scalability and manufacturability at a low cost. The filter can be realized in various integrated photonic platforms, including silicon carbide, silicon nitride, lithium niobate and aluminum nitride.

### CROSS-REFERENCE TO RELATED APPLICATIONS

This application claims priority to, and the benefit of, U.S. Provisional Patent Application Ser. No. 63/513,349 filed Jul. 12, 2023, the disclosure of which is incorporated by reference herein in its entirety.

ABBREVIATIONS

| | |
|---|---|
| 3C-SiC | cubic silicon carbide |
| 3C-SiCoI | 3C-SiC-on-insulator |
| α-Si | amorphous silicon |
| ALD | atomic layer deposition |
| AlN | aluminum nitride |
| AlNoI | AlN-on-insulator |
| Al₂O₃ | aluminum oxide |
| c-Si | crystalline silicon |
| CMOS | complementary metal oxide semiconductor |
| CVD | chemical vapor deposition |
| DRIE | deep reactive ion etching |
| EME | eigenmode expansion |
| ER | extinction ratio |
| IL | insertion loss |
| LN | lithium niobate |
| LNoI | LN-on-insulator |
| LPF | long-pass filter |
| NIR | near-infrared |
| OSA | optical spectrum analyzer |
| poly-Si | polycrystalline silicon |
| SEM | scanning electron microscope |
| SiC | silicon carbide |
| SiCoI | SiC-on-insulator |
| SPD | single-photon detector |
| SPDC | spontaneous parametric down-conversion |
| TE | transverse-electric |
| TM | transverse-magnetic |
| UMZI | unbalanced Mach-Zehnder interferometer |

### TECHNICAL FIELD

This application relates to an optical filter for long-pass filtering an incoming light beam, a light-conversion device utilizing the optical filter for generating an output light beam from an input laser beam, and an optical system realizable on an integrated photonic platform and employing the light-conversion device.

### BACKGROUND

Monolithic nonlinear and quantum photonic chips are promising for technological applications on a compact footprint without losing photons to inter-chip coupling losses. The nonlinear chips potentially enable on-chip wavelength conversions while the quantum chips enable quantum state preparation and manipulation functionalities, including quantum metrology, quantum communications and quantum computing.

On-chip nonlinear and quantum light sources as key integrated components have been demonstrated on various material platforms and through different photon generation processes. Single-photon emissions from color centers have been demonstrated in an integrated SiCoI platform where the SiC used in the platform is 4H—SiC [1], [2], and in suspended 3C—SiC resonators [3], [4]. These color centers impose a pump laser in a shorter wavelength and emit photons in the NIR wavelengths. Second-order optic nonlinearity-based nonlinear and photon-pair sources have been demonstrated on an integrated 3C—SiCoI platform [5], [6], an integrated AlNoI platform [7] and a LNoI platform [8]. The photon-pair sources frequency-down-convert the pump light in 780 nm into photon-pairs in the 1550 nm wavelengths through SPDC. SPDs using niobate nitride nanowires working in cryogenic temperatures have been demonstrated on various heterogeneously integrated material platforms [9], [10].

Beside on-chip nonlinear and quantum light sources and SPDs, on-chip pump-rejection filters are one essential building-block component for integrated quantum photonic circuits, but they remain relatively less explored in the art. The excess on-chip pump photons must be removed before interacting with down-stream components and photon detection. For example, a reasonable photon-counting rate of 1 MHz of the generated photons is about 120 dB weaker in power than an on-chip pump power of 1 mW. By cascading multiple stages of optical microring-based filters [10] or Mach-Zehnder interferometers [11], one can attain wavelength-selective isolations of a few tens of dB. However, these wavelength-agile cascaded filters limit the single-photon and photon-pair sources to narrow spectral bands. These filters further impose careful active wavelength alignments among all the individual filter stages. The use of active thermal and electric controls for aligning the filter wavelengths consumes extra energy and computing resources. Long gratings [12], directional coupler-based filters adopting integrated gratings [14] and tapered waveguides [15] enable a reasonable ER and a relatively broad bandwidth. However, these designs still demand cascading of carefully designed filter stages, which tends to increase the IL and requires precision fabrication processes.

There is a need in the art for an improved design not requiring precision fabrication processes while achieving a high value of ER.

### SUMMARY

A first aspect of the present disclosure is to provide an optical LPF for long-pass filtering an incoming light beam to yield a filtered light beam. The incoming light beam includes a desired light component and an undesired light component. The desired light component has one or more first constituent wavelengths. The undesired light component has one or more second constituent wavelengths. Each of the one or more first constituent wavelengths is longer than each of the one or more second constituent wavelengths.

The filter comprises a waveguide core and a selective-absorber layer. The waveguide core is used for receiving the incoming light beam, propagating the desired and undesired light components inside the waveguide core, and outputting the filtered light beam. The selective-absorber layer is deposited on the waveguide core. The selective-absorber layer is composed of an indirect-bandgap semiconductor material selected to have a bandgap energy greater than a maximum photon energy associated with the one or more first constituent wavelengths and less than a minimum photon energy associated with the one or more second constituent wavelengths such that when the desired and undesired light components interact with the selective-absorber layer during propagation inside the waveguide core, the undesired light component is attenuated while an optical power of the desired light component is retained.

Note that the filter is formed by a simple process of depositing the selective-absorber layer onto the waveguide core. This simple process of fabricating the filter alleviates the need for a precision process in filter fabrication. Furthermore, using the indirect-bandgap semiconductor material for absorption of undesired light component while retaining the desired light component allows a high ER value to be achieved.

In certain embodiments, the indirect-bandgap semiconductor material is selected to be α-Si or poly-Si. The selective-absorber layer may have a thickness of less than or equal to 100 nm.

In certain embodiments, the waveguide core is realized as a strip waveguide.

In certain embodiments, the waveguide core is realized as a rib waveguide.

In certain embodiments, the waveguide core is composed of 3C—SiC.

In certain embodiments, the waveguide core is composed of a material selected from SiC, LN and AlN.

In certain embodiments, the filter further comprises an optical-insulator layer on which the waveguide core is positioned. The optical-insulator layer provides a first reflective interface between the waveguide core and the optical-insulator layer to reflect the desired light component during propagation of the desired light component inside the waveguide core.

In certain embodiments, the optical-insulator layer is composed of SiO₂.

In certain embodiments, respective materials forming the optical-insulator layer and waveguide core are selected to allow total internal reflection to occur to the desired light component at the first reflective interface.

In certain embodiments, the filter further comprises a cladding deposited on at least a combined body consisting of the selective-absorber layer and the waveguide core. Particularly, the cladding is an optical-insulator cladding providing a second reflective interface between the waveguide core and the optical-insulator cladding to reflect the desired light component during propagation of the desired light component inside the waveguide core.

In certain embodiments, the cladding is composed of SiO₂.

In certain embodiments, the waveguide core is shaped to be straight.

In certain embodiments, the waveguide core is shaped to be bent.

In certain embodiments, the selective-absorber layer is shaped such that a non-filter section of the waveguide core is abruptly transited into a filter section thereof, where the filter section is a first longitudinal section of the waveguide core being entirely covered with the selective-absorber layer, and the non-filter section is a second longitudinal section of the waveguide core being entirely not covered with any of the selective-absorber layer.

In certain embodiments, a longitudinal end of the selective-absorber layer has a tilted contour overlying a transition region between the non-filter section and the filter section such that the non-filter section is progressively transited into the filter section.

In certain embodiments, the longitudinal end of the selective-absorber layer has a one-stage taper contour overlying the transition region such that the non-filter section is progressively transited into the filter section.

In certain embodiments, the longitudinal end of the selective-absorber layer has a two-stage taper contour overlying the transition region such that the non-filter section is progressively transited into the filter section.

A second aspect of the present disclosure is to provide a light-conversion device for generating an output light beam from an input laser beam.

The light-conversion device comprises one or more nonlinear quantum light sources collectively configured to perform a SPDC of the input laser beam to nonlinearly generate a first light beam such that the first light beam includes a desired light component and an undesired light component. The desired light component has one or more first constituent wavelengths. The undesired light component has one or more second constituent wavelengths. Each of the one or more first constituent wavelengths is longer than each of the one or more second constituent wavelengths. The light-conversion device further comprises any of the embodiments of the optical long-pass filter as disclosed above for long-pass filtering the first light beam to yield the output light beam. The first light beam is regarded as the incoming light beam, and the filtered light beam is regarded as the output light beam.

A third aspect of the present disclosure is to provide an optical system.

The optical system comprises any of the embodiments of the light-conversion device as disclosed above. In addition, the optical system further comprises one or more photonic circuits for processing the output light beam.

In certain embodiments, the optical system is realized as an integrated photonic chip.

Other aspects of the present disclosure are disclosed as illustrated by the embodiments hereinafter.

### BRIEF DESCRIPTION OF THE DRAWINGS

FIG. 1 depicts a prototype LPF realized as an α-(poly-) Si-based on-chip LPF for an integrated SiCoI quantum photonic platform.

FIG. 2 schematically depicts top and cross-sectional views of the prototype LPF as used in proof-of-concept experiments, illustrating the structure of the prototype LPF.

FIG. 3 plots IL results for simulated transmission of TE- and TM-polarized modes for light beams of 1550 nm and 780 nm in wavelength under a filter length of 1 mm for the prototype LPF.

FIG. 4 plots simulated mode-field amplitude distributions for TE- and TM-polarized modes in transmission of light beams of 780 nm and 1550 nm within the first 10 μm of the waveguide in the propagation direction inside the prototype filter under different values of Si-layer thickness.

FIG. 5 depicts a fabrication process flow of fabricating samples of the prototype LPF.

FIG. 6 shows two images regarding the prototype LPF as fabricated, where subplot (a) of FIG. 6 is an image of fabricated filters with different filter lengths, and subplot (b) thereof shows a SEM image of a waveguide-to-filter transition region.

FIG. 7 shows lens-to-lens normalized transmission spectra for the TE- and TM-polarizations under different filter lengths as used in the prototype LPF, where: subplots (a) and (b) show corresponding spectra obtained for the TE-polarization and the TM-polarization, respectively; subplots (c) and (d) show corresponding spectra for the TE-polarization and the TM-polarization, respectively, over the 780 nm wavelengths (765 nm to 795 nm); subplots (c) and (f) are near-field images output butt-couplers obtained from a reference waveguide (with a 0 μm-length filter) and a waveguide with a 100 μm-length filter; and subplot (g) shows wavelength-averaged transmission gains over three wavelength windows (1550/1310/780 nm) for TE and TM polarizations under various filter lengths.

FIG. 8 plots output spectra captured by an OSA with and without the 780 nm pump light coupled into the prototype LPF having a length of 100 μm, showing no re-emission above the −90 dB level under a condition of 1 mW on-chip pump power.

FIG. 9 depicts a top view, a longitudinal cross-sectional view and a lateral cross-sectional view of an optical LPF in accordance with an exemplary embodiment of the present disclosure.

FIGS. 10A-10D depict some embodiments of the disclosed optical LPF in lateral cross-sectional view, in which:

FIG. 10A depicts, as a reference, a first LPF that is the exemplary embodiment of the optical LPF as disclosed in FIG. 9, where an air cladding is used in the first LPF, and the waveguide core of the first LPF is a strip waveguide;

FIG. 10B depicts a second LPF obtained from the first LPF by using a rib waveguide instead of the strip waveguide as the waveguide core;

FIG. 10C depicts a third LPF obtained from the first LPF by further including a cladding deposited over a selective-absorber layer and the waveguide core; and

FIG. 10D depicts a fourth LPF formed from the first LPF by using the rib waveguide instead of the strip waveguide as the waveguide core, and by including the cladding.

FIGS. 11A and 11B depict two further embodiments of the disclosed optical LPF, in which:

FIG. 11A depicts a fifth LPF having a straight waveguide core; and

FIG. 11B depicts a sixth LPF having a bent waveguide core.

FIGS. 12A-12D depict some waveguide-to-filter transition designs for the disclosed optical LPF, in which:

FIG. 12A shows an abrupt transition;

FIG. 12B shows a tilted transition;

FIG. 12C shows a one-stage tapering transition; and

FIG. 12D shows a two-stage tapering transition.

FIG. 13 depicts a schematic diagram of an exemplary embodiment of a disclosed optical system, where the optical system includes a light-conversion device, which includes the disclosed optical LPF.

Skilled artisans will appreciate that elements in the figures are illustrated for simplicity and clarity and have not necessarily been depicted to scale.

### DETAILED DESCRIPTION

The disclosure will be more fully described below with reference to the accompanying drawings. However, the present disclosure may be embodied in a number of different forms and should not be construed as being limited to the embodiments described herein.

The present disclosure is concerned with an optical LPF for long-pass filtering an incoming light beam, a light-conversion device utilizing the optical LPF for generating an output light beam from an input laser beam, and an optical system realizable on an integrated photonic platform and employing the light-conversion device.

The Inventors have made the following observations leading to the development of the disclosed optical LPF. Indirect-bandgap semiconductor materials are natural LPFs or absorbers for short wavelengths because they provide reasonable absorption for photons exceeding their bandgap energy without an efficient radiative recombination. While the intrinsic material absorption of these indirect-bandgap semiconductor materials for light within the transparent window is negligible for a centimeter-scale photonic chip. Among readily accessible conventional semiconductor materials, α-Si and poly-Si are promising candidates because these two materials have an energy bandgap of ˜1.14 eV and absorb pump light in the visible/NIR wavelengths shorter than 1.1 μm while the two materials are largely transparent to light in the telecommunications O-, C-, and L-bands. The α-(poly-) Si material can be readily deposited on substrates using CVD furnaces in a CMOS foundry. The α-(poly-) Si material features a higher structural disorder than c-Si, thus providing a larger density of states [16] than c-Si. The absorption coefficient of α-Si is about an order of magnitude greater than that of the c-Si in the visible spectrum [17]. It is known that a deposition temperature exceeding 680° C. can partially crystalize α-Si into poly-Si and weaken the absorption capability [17]. Due to a better capability of light absorption than poly-Si and a simple deposition process on a wafer at a low cost, α-Si has been widely adopted in solar cells [18]. The α-Si material is also deposited on a silicon nitride photonic platform to serve as an on-chip microheater because the absorbed light can be converted into heat [19].

The Inventors have also observed that the disclosed optical LPF can be fabricated by a simple process of depositing a thin film of α-(poly-) Si layer. Advantageously, a precision process is not required in fabricating the disclosed optical filter.

In the present disclosure, a prototype LPF is first provided as a representative case for illustration of the claimed invention. The prototype LPF is a passive on-chip pump-rejection LPF targeted for filtering off the pump light component in 780 nm in a polychromatic light beam having 780 nm and 1550 nm light components, and is integrated on an integrated photonic platform. Generalization of the details of the prototype LPF will then follow for developing the claimed invention.

### A. Prototype LPF

The prototype LPF utilizes a thin-film α-(poly-) Si layer (of thickness less than 100 nm) deposited on the top surface and on the sidewalls of the integrated waveguides to reject the pump light in the visible/NIR wavelengths shorter than 1.1 μm by intrinsic material absorption along the waveguide propagation direction while the nonlinearly generated (signal and idler) light in the longer NIR wavelengths in the transparent window of the thin film remains propagating without significant absorption or mode perturbation. Such a waveguide structure with a properly designed absorbing film thickness offers a pump-rejection ratio of exceeding 120 dB within a compact filter length of 1 mm. The prototype LPF is applicable for efficient on-chip pump-rejection purposes on integrated quantum photonic chips.

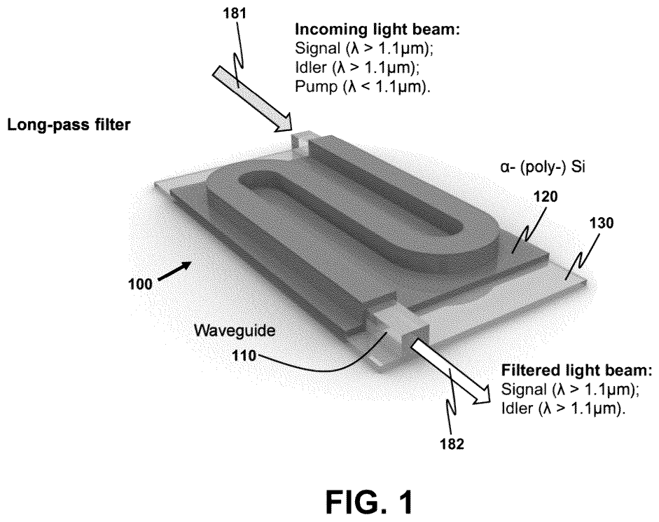

FIG. 1 depicts a schematic diagram of the prototype LPF (referenced as 100), realized as an α-(poly-) Si-based on-chip LPF for an integrated SiCoI quantum photonic platform. The prototype LPF 100 is formed with an integrated waveguide structure 110 for guiding and propagating an incoming light beam 181. The incoming light beam 181 is composed of a signal, an idler and a pump. The signal and idler are light components with wavelengths longer than 1100 nm while the pump is another light component with a wavelength shorter than 1100 nm. A thin layer 120 of α-(poly-) Si is deposited onto a segment of the integrated waveguide structure 110 for progressively absorbing the pump without attenuation to, or with only negligible attenuation to, the signal and idler. As a result, the waveguide structure 110 outputs a filtered light beam 182 with only the signal and idler. The waveguide structure 110 can be fabricated in various material platforms, including SiC, LN and AlN. An optical-insulator layer 130, which has a lower material refractive index compared with the waveguide material, is used for confining the signal and idler by total internal reflection, and can be fabricated by various materials. Light beams of different wavelengths propagate under different optical modes with different spatial distributions in the waveguide structure 110. Light beams with wavelengths shorter than ˜1.1 μm overlapping with the absorption region of the α-(poly-) Si layer are strongly attenuated.

Note that the footprint of the prototype LPF 100 can be made compact if the waveguide structure 110 is designed properly with a bending shape. As an example shown in FIG. 1, the waveguide structure 110 has a serpentine shape for space saving. Note that other shapes can also be used to form the waveguide structure 110. A straight waveguide may also be used.

Proof-of-concept experiments for substantiating the prototype LPF 100 on a 3C—SiCoI platform were conducted.

### A.1. LPF Design

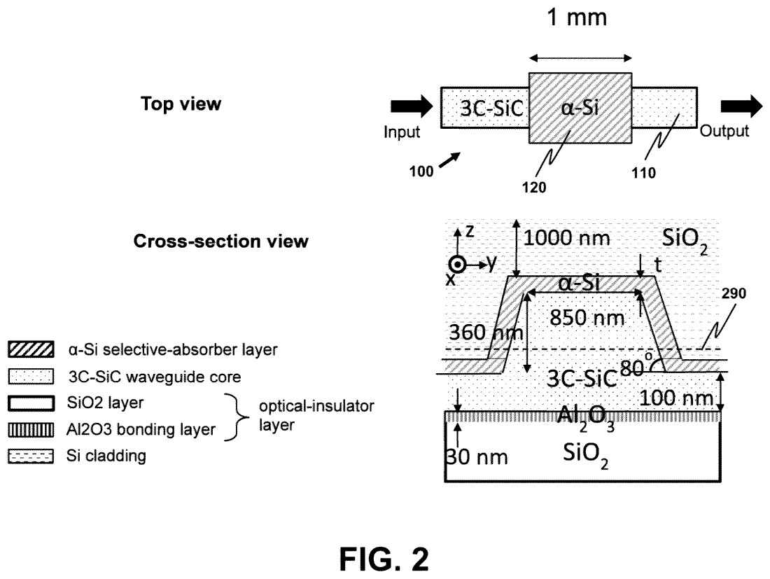

FIG. 2 schematically depicts top and cross-sectional views of the prototype LPF 100 for illustrating its structure. In the design process, a 3C—SiC waveguide with a width, a SiC film thickness and a slab thickness of 850 nm, 460 nm, and 100 nm, respectively, was adopted in realizing the waveguide structure 110. A waveguide sidewall slope of ˜80° based on the device fabrication results was also adopted. These design dimensions were adopted based on requirements of other specific applications, and can be varied in practice. In the design process, it was assumed that the α-(poly-) Si layer covered the waveguide top surface and sidewalls uniformly. A 30 nm-thick Al₂O₃ bonding layer underneath a SiC film was adopted for bonding with a SiO₂ under-cladding layer. The whole waveguide structure 110 was surrounded by SiO₂ cladding. In numerical simulations of the design, standard material parameters of c-Si instead of those of α-(poly-) Si were used.

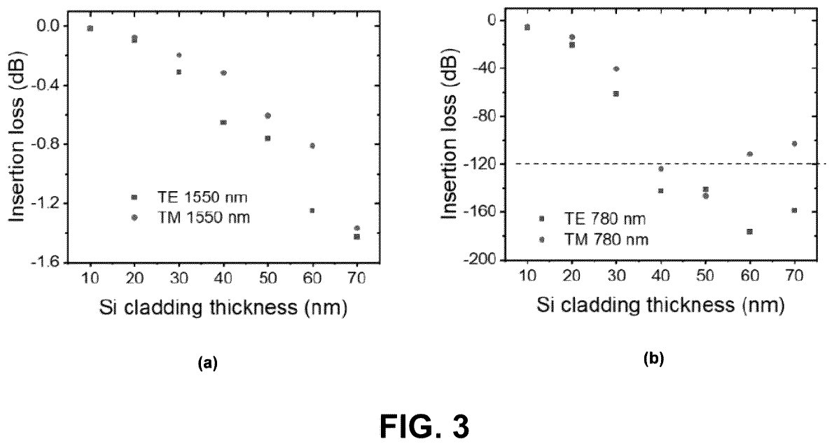

FIG. 3, in subplots (a) and (b), shows EME simulation results of optical transmissions assuming a waveguide length of 1 mm, where subplot (a) and (b) plot ILs against Si cladding thickness for light beams of 1550 nm and 780 nm, respectively, under TE/TM-polarized modes with a filter length of 1 mm. A small but increasing IL is observed for the 1550 nm wavelength due to the waveguide mode redistribution and confinement in the high-refractive-index Si layer. For the light beam with the 780 nm wavelength, the absorption is determined by the degree of spatial overlap between the mode field and the Si layer 120. The modal overlap does not monotonically increase with the Si layer thickness t.

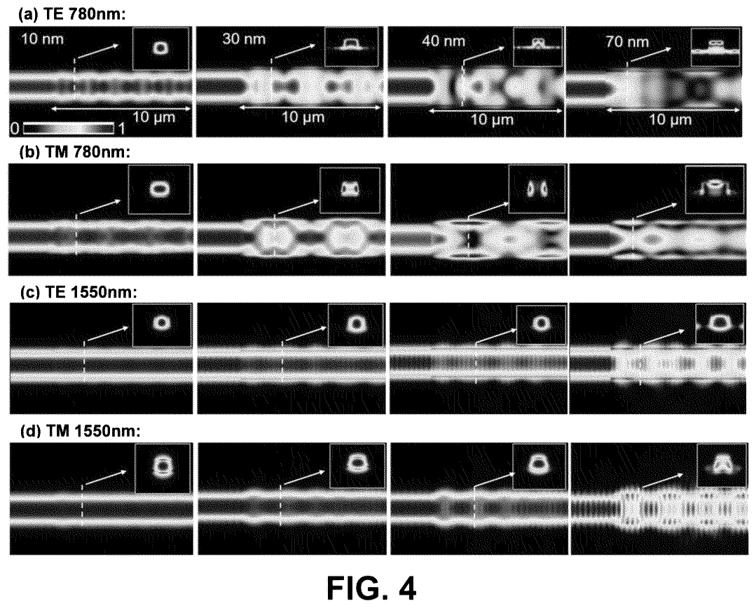

FIG. 4, in subplots (a)-(d), plots simulated mode-field amplitude distributions for TE- and TM-modes in 780 nm and in 1550 nm wavelengths within the first 10 μm of the waveguide 110 in the propagation direction under different values of the thickness t of the Si layer 120. The horizontal dashed line 290 shown in FIG. 2 indicates an x-y plane where the mode-field amplitude distributions were simulated. From the results of FIG. 4, it is observed that the 780 nm waveguide modes exhibit a higher-order mode interference with t at or exceeding 30 nm. It results in different spatial overlaps with periodically coupling the 780 nm light into the Si thin-film guided mode, as shown in insets of subplots (a) and (b) of FIG. 4. With t=70 nm, even the TE- and TM-polarized modes in the 1550 nm wavelength exhibit interference. Based on the simulation results, a thin-film α-Si layer thickness of 40 nm was adopted in device fabrication to attain a significant targeted absorption loss of ˜120 dB/mm for 780 nm light (pump) while maintaining a negligible IL of below 1 dB for 1550 nm light (signal and idler).

### A.2. Fabrication

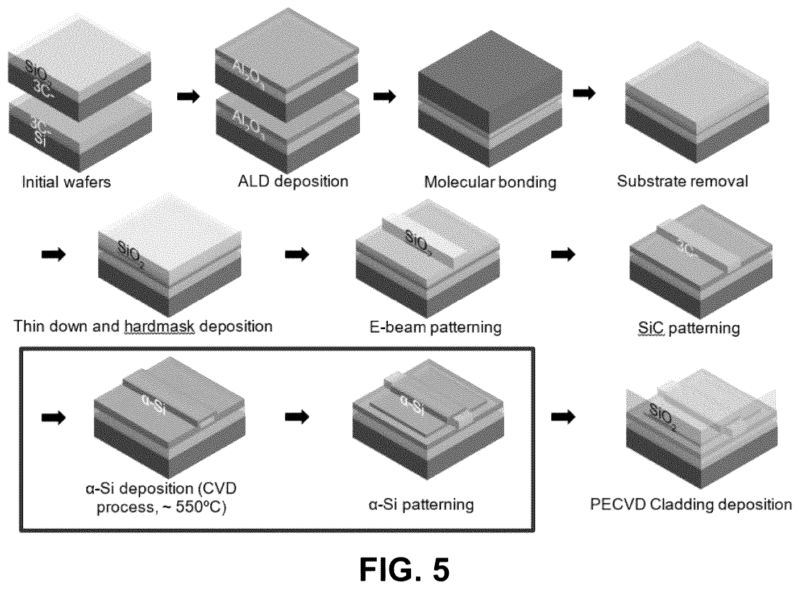

The prototype LPF was fabricated by a fabrication process flow shown in FIG. 5. Commercial 4-inch epitaxial 3C—SiC-on-Si wafers were adopted in the fabrication process. A SiC film used in fabricating the waveguide 110 had a thickness of 1.5 μm, and the film was polished chemically and mechanically. A 4-inch Si substrate with a thermal SiO₂ layer of 3 μm was adopted and used as a carrier wafer in wafer-to-wafer bonding. A standard 120° C. H₂SO₄ (98%):H₂O₂ (30%)=10:1 solution was first used to clean both wafers. The two wafers were then transferred into an Oxford ALD equipment to deposit a layer of Al₂O₃ with a thickness of 15 nm simultaneously, which gave a total Al₂O₃ layer thickness of 30 nm after the bonding step. After the deposition, the two wafers were put into contact and were pressed to initiate a pre-bonding. Then, the wafer pair was transferred into a Karl Suss SB6 bonder. The pre-bonded wafers were annealed at 300° C. in a vacuum for 3 hours to attain permanent bonding. After the bonding step, a Si grinder was deployed to remove the bulk of the Si substrate on the SiC side. The rest of the Si substrate was removed with a tetramethylazanium hydroxide solution heated to 80° C. The remaining SiC film after the substrate removal was less than 50% of the original wafer. The remaining parts were diced into small dices each of size 1.2 cm×1.2 cm.

The exposed SiC surface corresponded to the first layer of SiC epitaxially grown on a Si substrate. The first layer of SiC had a poor crystal quality due to lattice mismatch between 3C—SiC and Si. A DRIE recipe with SF₆ and O₂ was adopted to thin down the film to a target thickness of 460 nm as suggested by our numerical simulation results. A PECVD-produced SiO₂ layer of 500 nm in thickness was deposited on the 3C—SiC film as a hard mask. Electron-beam lithography and DRIE were employed to pattern the SiO₂ hard mask. The same SF₆/O₂ DRIE process was then used to pattern the SiC film. The SiC-to-SiO₂ selectivity is 1.45. The remaining SiO₂ hard mask was subsequently removed by using a buffered oxide etchant. The sample was transferred to a CVD furnace to deposit an α-Si layer with a 40 nm thickness. The deposition temperature was kept at 550° C. to avoid the α-Si film from being partially crystallized. After the α-Si deposition, an i-line photolithography process was used to cover the desired filter region with a photoresist. The α-Si layer elsewhere was completely removed by wet etching (Freckle etch solution). A PECVD SiO₂ upper-cladding layer of 1000 nm thickness was thereafter deposited to protect the whole sample. Finally, samples of the wafer were diced into columns for optical butt-coupling. The butt-coupling was adopted for conveniently in/out-coupling with various visible/NIR wavelengths.

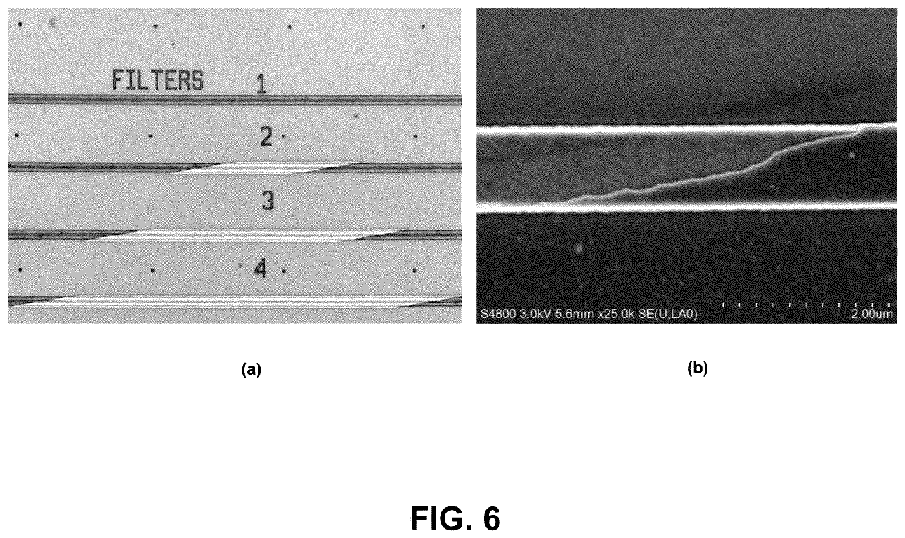

FIG. 6 shows two images regarding the fabricated prototype LPF. Subplot (a) of FIG. 6 is an image of fabricated filters with different filter lengths, where the filters have lengths of 0-300 μm in step of 100 μm. Subplot (b) thereof shows an SEM image of a waveguide-to-filter transition region. The transition region was designed such that the transition was in a tilted manner in order to gradually modulate the impedance mismatch between the waveguide region and the filter region. Note that, however, such a tilting structure was not accurately transferred during the wet etching, resulting in a roughened tilted transition.

### A.3. Experimental Results

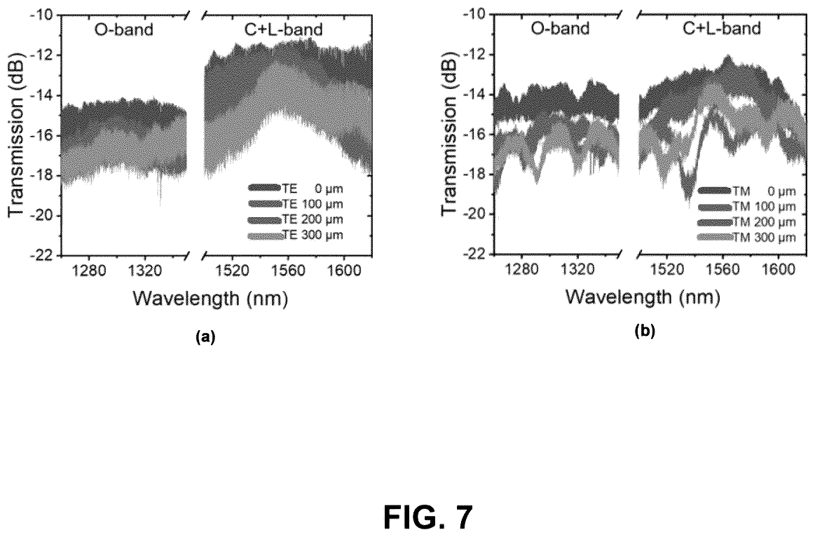

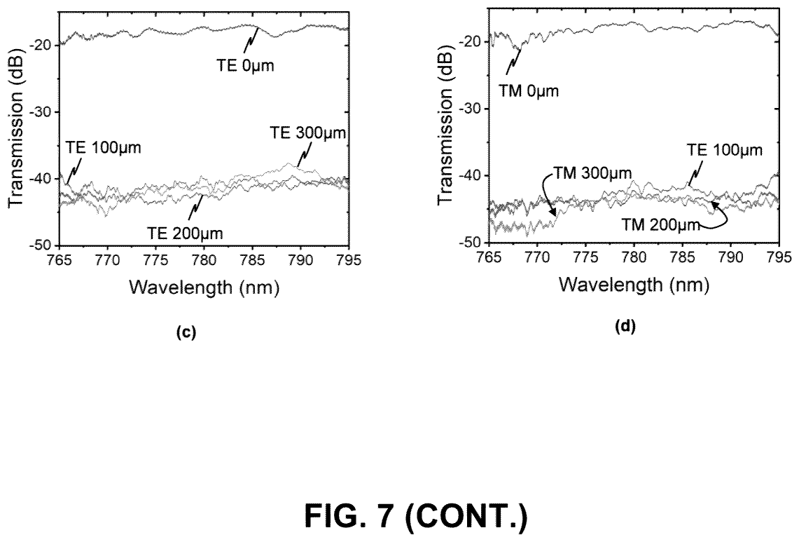

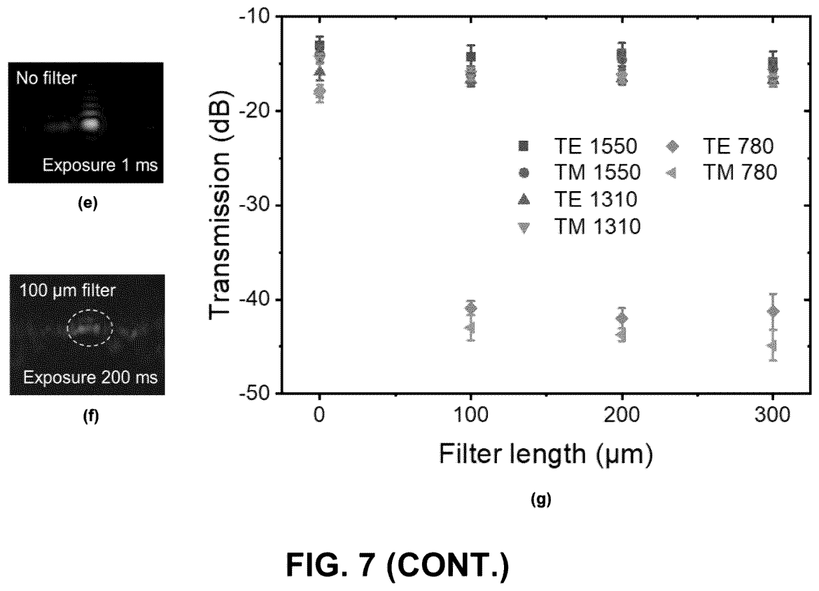

In the prototype LPF, a pair of long-working-distance objective lens (0.42 numerical aperture) was used for the input/output butt-coupling. Lens-to-lens normalized transmission spectra of the TE- and TM-polarizations under different filter lengths were experimentally obtained. Corresponding experimental results are shown in FIG. 7.

Subplots (a) and (b) of FIG. 7 show normalized transmission spectra in the O-, C-, and L-bands in the TE- and TM-polarizations for the fabricated filters with different lengths, where subplots (a) and (b) show the results for the TE-polarization and the TM-polarization, respectively. The results do not show a systematic increase in IL with the filter length increasing in 100 μm steps, suggesting that the passive waveguide loss in the transparent window is negligible under the considered scale of length. However, a systematic difference between the reference waveguide (i.e. the waveguide without covering with α-Si at all) and the three filters is observed.

Subplots (c) and (d) of FIG. 7 show normalized transmission spectra for the TE- and TM-polarizations in the 780 nm wavelengths (765˜795 nm), respectively. As straight waveguides were adopted in the filters, the background power caused by direct scattering of the input light is high with a value of ˜−40 dB. It is observed that, even for the shortest filter with a length of 100 μm, the transmitted light is at the background level of the scattering light. This observation is further confirmed by near-field images of output butt-couplers captured by a charge-coupled-device camera from the reference waveguide and specifically from the 100 μm-length filter. The near-field images are respectively shown in subplots (c) and (f) of FIG. 7. The exposure times for getting the near-field images were 1 ms and 200 ms for subplots (e) and (f), respectively, corresponding to a 23 dB enhancement for the longer exposure. The transmitted light from the butt-coupler after the absorption was at the background level.

Subplot (g) of FIG. 7 shows wavelength-averaged transmission gains over three wavelength windows (1550/1310/780 nm) for TE and TM polarizations under various filter lengths. (Note that a negative value of the transmission gain means a power loss during transmission.) Compared with the reference waveguide (namely, the one with 0 μm filter length), ILs of 0.8±1.0 dB and 1.9±0.5 dB for the TE- and TM-polarized waveguide modes in the O-band are observed while ILs of 1.3±1.2 dB and 1.5±0.9 dB for the TE- and TM-polarized waveguide modes in the C- and L-bands are obtained. For the transmissions at 780 nm wavelengths, lower-bound ILs are estimated to be 230±8 dB/mm and 248±12 dB/mm for the TE- and TM-polarized waveguide modes, respectively, based on the characterized 100 μm-length filter, limited by the scattering of the input light. The extracted/estimated IL values are significantly larger than the simulated ones, mainly because the material model adopted in numerical simulations was based on standard c-Si, known to have a smaller absorption coefficient compared with α-Si adopted in the prototype LPF.

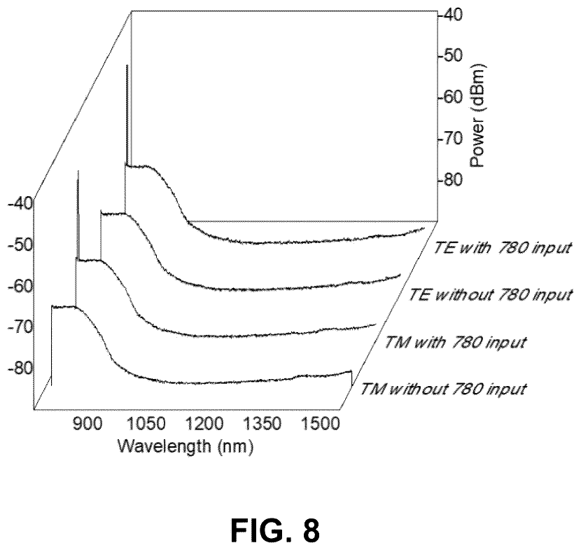

FIG. 8 shows the measured spectra using an OSA with and without the 780 nm light coupling into the 100 μm-length filter. If the 780 nm light was coupled into the filter, a pump power of 1 mW was used in obtaining the measured spectra. It is not observed with any significant optical power resulting from radiative recombination above or below the bandgap energy equivalent to a photon energy of ˜1100 nm up to 1550 nm. The measured spectra between ˜800 nm to 1550 nm are at the noise floor of the OSA. The result indicates no significant re-emission of light above the −90 dB level upon absorption of photons of the 780 nm light. This finding ensures that an on-chip LPF using an indirect-bandgap semiconductor absorber does not act as a secondary light source. This finding is critical towards applications of the on-chip LPF for quantum photonic circuits.

### B. Details of Embodiments of Present Disclosure

Embodiments of the present disclosure are developed as follows based on the details, examples, applications, experimental findings, etc., of the prototype LPF disclosed above mainly in Section A possibly with generalization and extension.

A first aspect of the present disclosure is to provide an optical LPF for long-pass filtering an incoming light beam to yield a filtered light beam. The incoming light beam includes a desired light component and an undesired light component. The desired light component has one or more first constituent wavelengths. The undesired light component has one or more second constituent wavelengths. Each of the one or more first constituent wavelengths is longer than each of the one or more second constituent wavelengths.

Refer to FIG. 1. As an example for illustration, the incoming light beam 181 received by the prototype LPF 100 has the desired light component composed of the signal and idler, and the undesired light component being the pump. The signal and idler have respective wavelengths longer than 1100 nm whereas the pump has a wavelength less than 1100 nm.

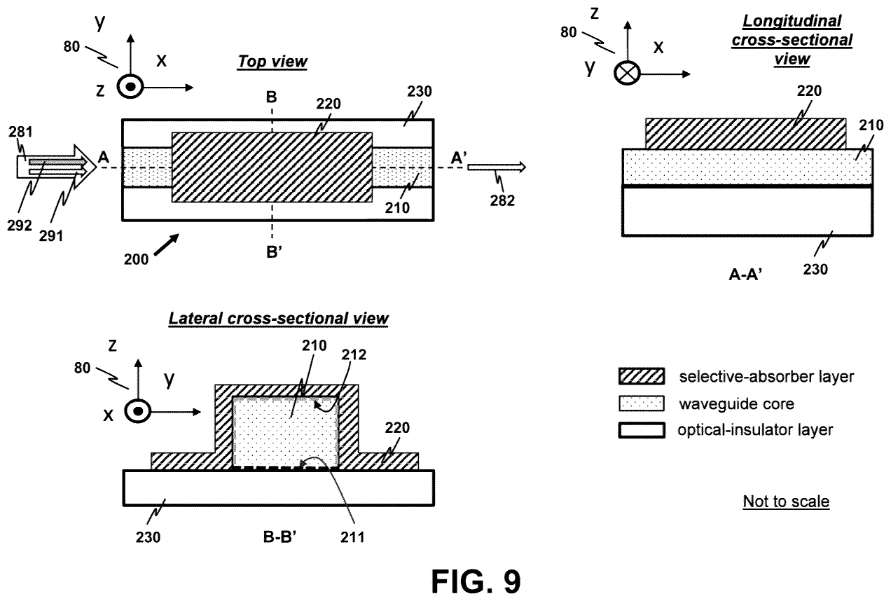

Exemplarily, the disclosed optical LPF is described as follows with the aid of FIG. 9, which depicts a top view, a longitudinal cross-sectional view (A-A′) and a lateral cross-sectional view (B-B′) of an exemplary optical LPF 200.

A three-dimensional rectangular coordinate system 80 is defined herein as shown in FIG. 9. In the coordinate system 80, the z-direction is interpreted as a reference vertical direction. Herein in the specification and appended claims, positional and directional words such as “above,” “below,” “higher,” “upper,” “lower,” “top,” “bottom” and “horizontal” are interpreted with reference to the z-direction.

The LPF 200 is arranged to receive an incoming light beam 281 and output a filtered light beam 282. The incoming light beam 281 includes a desired light component 291 and an undesired light component 292. Each of constituent wavelength(s) of the desired light component 291 is longer than each of constituent wavelength(s) of the undesired light component 292.

The LPF 200 comprises a waveguide core 210 and a selective-absorber layer 220.

The waveguide core 210 corresponds to the waveguide structure 110 of the prototype LPF 100. The waveguide core 210 is used for receiving the incoming light beam 281, propagating the desired and undesired light components 291, 292 inside the waveguide core 210, and outputting the filtered light beam 282.

The selective-absorber layer 220, which corresponds to α-(poly-) Si layer 120 of the prototype LPF 100, is deposited on the waveguide core 210. The selective-absorber layer 220 is used for selectively absorbing the undesired light component 292 without attenuating the desired light component 291, or with only negligible attenuation to the desired light component 291 in comparison to absorption of the undesired light component 292, when the desired and undesired light components 291, 292 interact with the selective-absorber layer 220 during propagation of the desired and undesired light components 291, 292 inside the waveguide core 210. In particular, the selective-absorber layer 220 is composed of an indirect-bandgap semiconductor material selected to have a bandgap energy greater than a maximum photon energy associated with the one or more first constituent wavelengths and less than a minimum photon energy associated with the one or more second constituent wavelengths. It thereby causes the selective-absorber layer 220 to be energy-dissipating to the undesired light component 292 and non-dissipative to the desired light component 291. It follows that when the desired and undesired light components 291, 292 interact with the selective-absorber layer 220 during propagation of the desired and undesired light components 291, 292 inside the waveguide core 210, the undesired light component 292 is attenuated while an optical power of the desired light component 291 is retained. Note that the maximum photon energy associated with the one or more first constituent wavelengths is calculated by (1) computing one or more photon energies for one or more photons respectively having the one or more first constituent wavelengths, and (2) selecting the maximum value among the computed one or more photon energies. The minimum photon energy associated with the one or more second constituent wavelengths is obtained by a similar approach.

The indirect-bandgap semiconductor material may be selected to be α-Si or poly-Si. Usually, α-Si is preferred over poly-Si as the indirect-bandgap semiconductor material since α-Si generally has a better capability of light absorption than poly-Si and can be deposited onto a wafer by a simple deposition process at a low cost.

In certain embodiments, the selective-absorber layer 220 has a thickness of less than or equal to 100 nm. As demonstrated by the simulation results for the prototype LPF 100 in Section A, a thickness of 40 nm is sufficient for the α-Si layer 120 to achieve a high absorption loss of ˜120 dB/mm for the 780 nm light while maintaining a negligible IL of below 1 dB for the 1550 nm light.

In certain embodiments, the waveguide core 210 is composed of SiC. The SiC material used as the waveguide core 210 may be 3C—SiC. Other materials that may be used for forming the waveguide core 210 include LN and AlN.

Generally, the LPF 200 further comprises an optical-insulator layer 230 on which the waveguide core 210 is positioned. The optical-insulator layer 230 provides a first reflective interface 211 between the waveguide core 210 and the optical-insulator layer 230 to reflect the desired light component 291 during propagation of the desired light component 291 inside the waveguide core 210. Note that the first reflective interface 211 is required to be reflective to the desired light component 291 only but is not particularly designed to reflect the undesired light component 292 because the LPF 200 is required to ensure that the desired light component 291 is outputted from the LPF 200.

In certain embodiments, the first reflective interface 211 is formed due to occurrence of total internal reflection of the desired light component 291. It follows that respective materials forming the optical-insulator layer 230 and waveguide core 210 arc selected to allow total internal reflection to occur to the desired light component 291 at the first reflective interface 211. Accordingly, a first refractive index of the waveguide core 210 is higher than a second refractive index of the optical-insulator layer 230, where the first and second refractive indexes are measured at each of the one or more first constituent wavelengths. In certain embodiments, the optical-insulator layer 210 is composed of SiO₂.

Note that in the fabrication of the prototype LPF 100 as detailed above, the 30 nm-thick Al₂O₃ bonding layer was put underneath the SiC film (namely, the waveguide 110) for bonding with the SiO₂ under-cladding layer. Since the desired light component of interest to the prototype LPF 100 has constituent wavelengths around 1550 nm, the thickness of the bonding layer (30 nm) is considerably shorter than each wavelength of the light components. The SiO₂ under-cladding layer plays a determining role in realizing total internal reflection for the desired light component 291. Hence, the SiO₂ under-cladding layer is regarded as the optical-insulator layer 230 that forms the first reflective interface 211 with the waveguide core 210.

Alternative to relying on the total internal reflection, the first reflective interface 211 may be created by directly using a reflective material, e.g., gold, to form the optical-insulator layer 230, where the reflective material is reflective at each of the one or more first constituent wavelengths.

In the LPF 200 shown in FIG. 9, exposed areas of the waveguide core 210 and selective-absorber layer 220 is surrounded by air. Since the refractive index of air is almost one and is lower than respective refractive indexes of the waveguide core 210 and selective-absorber layer 220, a second reflective interface 212 similar to the first reflective interface 211 is created for reflecting the desired light component 291 back to the waveguide core 210 by total internal reflection. Note that the thickness of the selective-absorber layer 220 is in most cases considerably shorter than each constituent wavelength of the desired light component 291. For instance, the prototype LPF 100 was designed to have the α-Si layer of 40 nm in thickness whereas the desired light component of interest to the prototype LPF 100 had wavelength(s) around 1550 nm. Thus, the waveguide core 210 and surrounding air have major roles in setting up the total internal reflection mechanism and creating the second reflective interface 212.

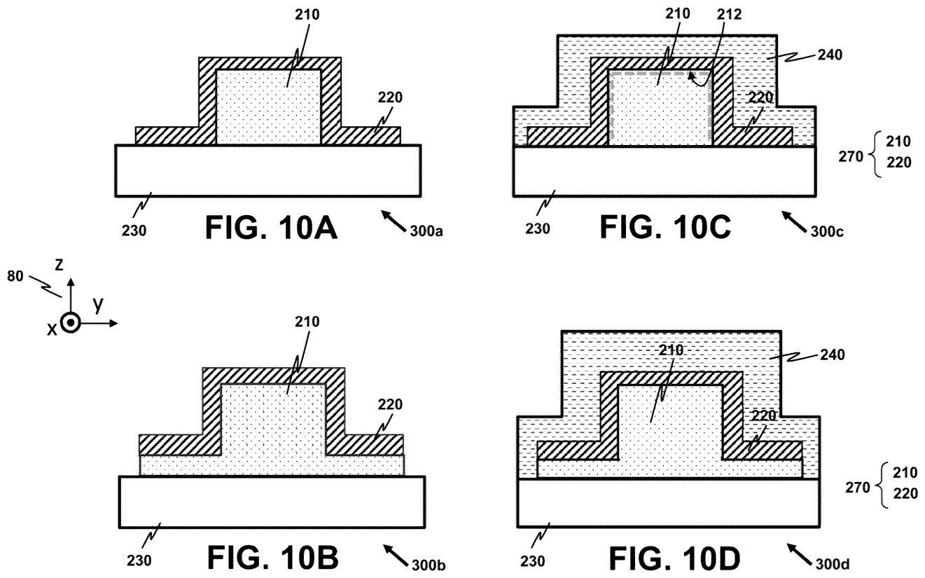

FIGS. 10A-10D depict some embodiments of the LPF 200 in lateral cross-sectional view.

As a reference, FIG. 10A depicts a first LPF 300a that is the LPF 200, the exemplary embodiment of the disclosed optical LPF, as described above. Note that an air cladding, which is a cladding layer formed by air, is used in the first LPF 300a. Furthermore, the waveguide core 210 is a strip waveguide. A strip waveguide is basically a strip of a layer confined between cladding layers. A rectangular waveguide is one example of the strip waveguide.

FIG. 10B depicts a second LPF 300b, which is a variant of the first LPF 300a by using a rib waveguide instead of the strip waveguide as the waveguide core 210. A rib waveguide is a waveguide in which a guiding layer basically has a slab with a strip (or several strips) superimposed onto the slab.

FIG. 10C depicts a third LPF 300c, which the first LPF 300a further including a cladding 240 deposited on at least a combined body 270 consisting of the selective-absorber layer 220 and the waveguide core 210. In addition to forming a protective layer for protecting the combined body 270, the cladding 240 is an optical-insulator cladding providing the second reflective interface 212 between the waveguide core 210 and the cladding 240 to reflect the desired light component 291 during propagation of the desired light component inside the waveguide core 210. In certain embodiments, the cladding 240 is composed of SiO₂.

FIG. 10D depicts a fourth LPF 300d, which is formed from the first LPF 300a by (1) using the rib waveguide instead of the strip waveguide as the waveguide core 210, and (2) including the cladding 240, which is deposited on at least the combined body 270 that consists of the selective-absorber layer 220 and the waveguide core 210.

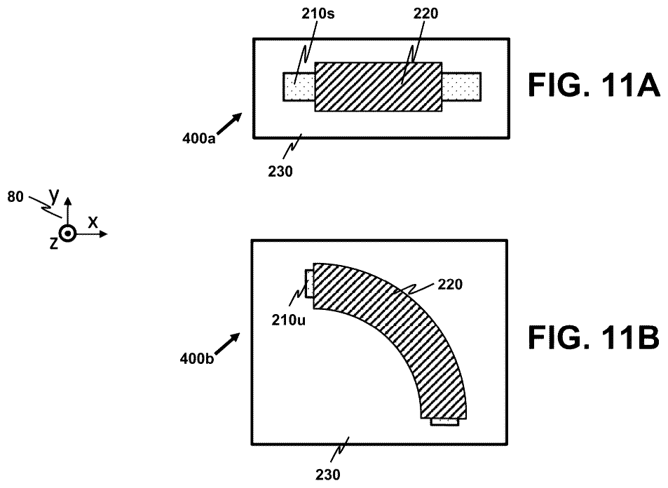

FIGS. 11A and 11B depict a fifth LPF 400a and a sixth LPF 400b, respectively, as two further embodiments of the disclosed optical LPF. The fifth and sixth LPFs 400a, 400b differ in that the fifth LPF 400a has a straight waveguide core 210s while the sixth LPF 400b has a bent waveguide core 210u. As such, the disclosed optical LPF has the flexibility of shaping the waveguide core 210 to be straight or bent. As demonstrated by the prototype LPF 100, this flexibility enables the footprint of the prototype LPF 100 to be made compact.

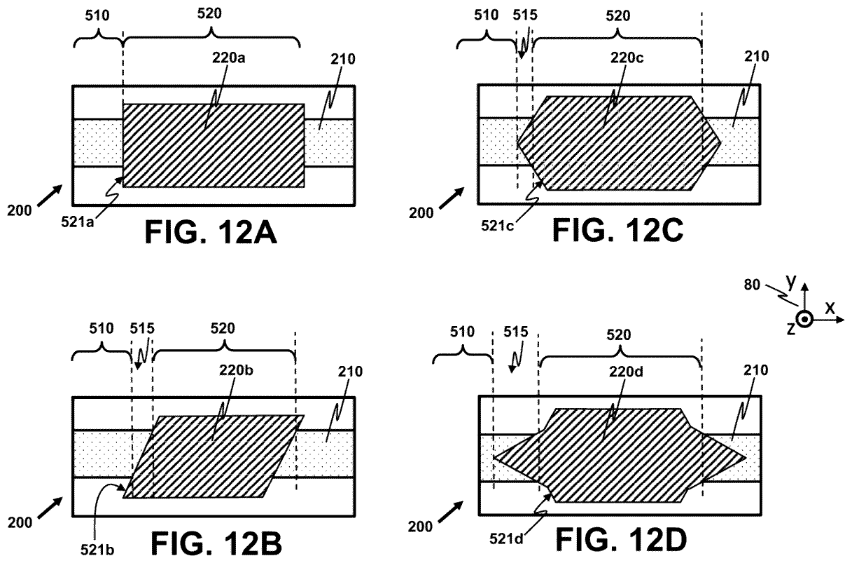

FIGS. 12A-12D depict various waveguide-to-filter transition designs for the disclosed optical LPF. Particularly, FIG. 12A shows an abrupt transition; FIG. 12B shows a tilted transition; FIG. 12C shows a one-stage tapering transition; and FIG. 12D shows a two-stage tapering transition. Before the various transitions are elaborated, it is instructive to define several regions of the waveguide cores.

A filter section 520 of the waveguide core 210 is a first longitudinal section of the waveguide core 210 being entirely covered with the selective-absorber layer 220a/b/c/d. A non-filter section 510 of the waveguide core 210 is a second longitudinal section of the waveguide core 210 being entirely not covered with any of the selective-absorber layer 220a/b/c/d. A transition region 515 of the waveguide core 210 is a third longitudinal section of the waveguide core 210 being located between the non-filter section 510 and the filter section 520.

In the abrupt transition as shown in FIG. 12A, the transition region is absent. The selective-absorber layer 220a is shaped such that the non-filter section 510 is abruptly transited into the filter section 520. Specifically, a longitudinal end of the selective-absorber layer 220a has a contour 521a aligned with a cross-sectional plane of the waveguide core 210.

In the tilted transition as shown in FIG. 12B, a longitudinal end of the selective-absorber layer 220b has a tilted contour 521b overlying the transition region 515 such that the non-filter section 510 is progressively transited into the filter section 520.

In the one-stage tapering transition as shown in FIG. 12C, a longitudinal end of the selective-absorber layer 220c has a one-stage taper contour 521c overlying the transition region 515 such that the non-filter section 510 is progressively transited into the filter section 520.

In the two-stage tapering transition as shown in FIG. 12D, a longitudinal end of the selective-absorber layer 220d has a two-stage taper contour 521d overlying the transition region 515 such that the non-filter section 510 is progressively transited into the filter section 520.

Non-abrupt transitions as shown in FIGS. 12B-12D have an advantage of reducing an impedance mismatch between the non-filter section 510 and the filter section 520 in comparison to an abrupt transition as shown in FIG. 12A.

A second aspect of the present disclosure is to provide a light-conversion device for generating an output light beam from an input laser beam, where the light-conversion device includes any of the embodiments of the disclosed optical LPF.

A third aspect of the present disclosure is to provide an optical system including any of the embodiments of the disclosed light-conversion device. The disclosed optical system may be realized as an integrated photonic chip. Furthermore, the disclosed optical system may find applications in, e.g., quantum communications and internet, quantum computers, quantum metrology and sensing, etc.

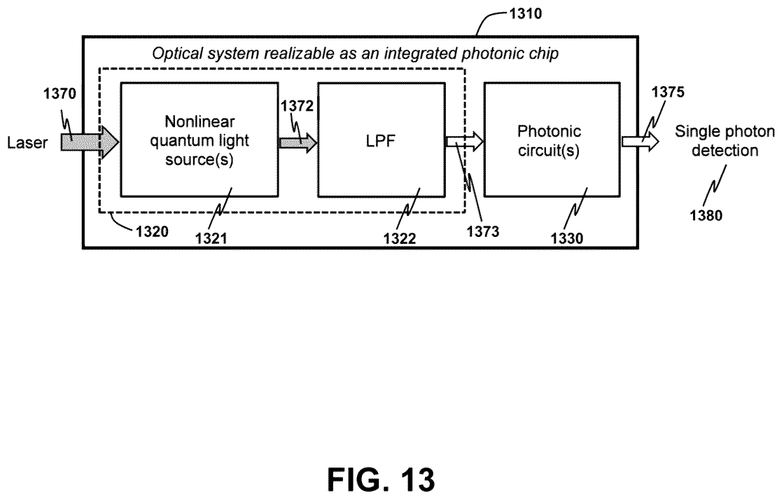

The optical system and light-conversion device as disclosed herein are exemplarily illustrated with the aid of FIG. 13, which depicts a schematic diagram of an exemplary embodiment of the disclosed optical system. As shown in FIG. 13, an optical system 1310 includes a light-conversion device 1320.

The light-conversion device 1320 is used for generating an output light beam 1373 from an input laser beam 1370. The light-conversion device 1320 comprises one or more nonlinear quantum light sources 1321 and an optical LPF 1322. The one or more nonlinear quantum light sources 1321 are collectively configured to perform a SPDC of the input laser beam 1370 to nonlinearly generate a first light beam 1372 such that the first light beam 1372 includes a desired light component and an undesired light component. The desired light component has one or more first constituent wavelengths. The undesired light component has one or more second constituent wavelengths. Each of the one or more first constituent wavelengths is longer than each of the one or more second constituent wavelengths. The optical LPF 1322 is realized as one of the embodiments of the disclosed optical LPF. The optical LPF 1322 is used for long-pass filtering the first light beam 1372 to yield the output light beam 1373. The first light beam 1372 defined for the light-conversion device 1320 is regarded as the incoming light beam 281 defined for the LPF 200. Similarly, the filtered light beam 282 is regarded as the output light beam 1373.

The optical system 1310 comprises the light-conversion device 1320 and one or more photonic circuits 1330. The one or more photonic circuits 1330 receive the output light beam 1373 from the light-conversion device 1320, and process the output light beam 1372 to generate one or more optical signals 1375.

The generated one or more optical signals 1375 may be detected by single photon detection 1380.

Practically, the optical system 1310 may be realized as an integrated photonic chip. Similarly, the light-conversion device 1320 is realizable on the integrated photonic chip.

### C. Comparison with Prior-Art Techniques

Some remarks regarding improvements of present disclosure over prior art are given as follows. Before the remarks are made, a review of prior-art publications under consideration is provided.

Reference [11] demonstrated a cascaded microring resonator-based wavelength filter with a high ER. In [11], a device for TE polarization was designed, and on-chip micro-heaters were utilized to align each of the microring elements to a desired wavelength. The

maximum filtering bandwidth achieved was 125 GHz. However, the technique of [11] requires an accurate control of ten microheaters to tune the microring elements, thus imposing energy consumption. The filtering bandwidth is limited to 125 GHz around a target wavelength. It is not convenient for applications (e.g., SPDC-based photon sources) that require flexibility in the pump light wavelength. This technique only works for the designed TE-polarization propagation. The filtering of the TM polarization imposes an alternative design given the polarization-dependent microring resonances.

Reference [12] demonstrated a standard Bragg-grating-based reflector for a targeted pump wavelength with a target ER of 100 dB. The technique of [12] requires a grating period of 320 nm and a length of 2.576 mm. However, the filtering bandwidth demonstrated in [12] is narrow (<0.01 nm) and fixed at a target wavelength. This technique cannot be applied to applications (e.g., SPDC-based photon sources) that require tuning of the pump light wavelength. This technique imposes the requirement of accurate fabrication of the grating.

Reference [13] demonstrated an ER of 56 dB using cascaded UMZIs with 4 stages. The ER can be further improved by cascading more than 4 stages. The filtering bandwidth demonstrated was over 1 nm. This technique requires accurate fabrication of the cascaded UMZIs to attain the required spectral overlap among the filter bands of the single stages while not involving an active wavelength alignment. The filtering bandwidth of this technique is still limited for applications (e.g., SPDC-based photon-sources) requiring a wide bandwidth for rejecting (pump) light in the short wavelength.

Reference [14] demonstrated a filter based on a cascaded 16-stage grating-assisted contra-directional coupler. This technique demonstrated an ER of 68.5 dB and a filtering bandwidth of 3 nm. The technique combines the filtering of the grating and the directional couplers. The grating featured a period of 244 nm and a duty cycle of 50%. The total length of the device was 2 mm. However, the filtering bandwidth of this technique is still limited to a center wavelength and thus is not convenient for applications (e.g., SPDC-based and color-center-based quantum light sources) requiring flexibility in the choice of the pump light wavelength. This grating period of 244 nm adopted in this technique requires an advanced device fabrication facility.

Reference [15] demonstrated a 70 dB attenuation for a wavelength near 775 nm with an IL of 3 dB at the 1550 nm by adopting a cascaded tapered directional coupler-based filter. This technique has a filter bandwidth of 16 nm around 775 nm and a bandwidth of 50 nm for the passband at 1550 nm. However, the filtering bandwidth used by this technique is still limited. The IL increases with the number of cascading filter stages. One can anticipate that a total ER exceeding 100 dB would render the IL to exceed 3 dB for the 1550 nm wavelength, which would result in a reduction of photon-pair counts by exceeding 6 dB.

Compared with the above-mentioned techniques disclosed in [11]-[15], the present disclosure enables simultaneously a significantly wider filtering band for the pump light in the short wavelengths and a pass band for the generated light in the long wavelengths, based on the deposited thin-film silicon intrinsic absorption. The rejection band naturally covers the typical pump-light wavelength of choice in the literature at 532, 650, 780 and 900 nm for various on-chip photon-sources while the pass band spans the telecommunications bands around 1.31 μm and 1.55 μm.

Compared with all of the above-mentioned techniques, the optical LPF as disclosed herein is conceptually simple and does not require advanced fabrication facilities. The main design parameter of the LPF 200 is the thickness of the absorbing thin-film layer.

Compared with all of the above-mentioned techniques, the optical LPF as disclosed herein consumes a significantly smaller on-chip footprint, because the total filter structure is less than 1 mm in length, and one can bend the waveguide filter in compact shapes.

### References

There follows a list of references that are occasionally cited in the specification. Each of the disclosures of these references is incorporated by reference herein in its entirety.
[1] M. Radulaski, M. Widmann, M. Niethammer, J. L. Zhang, S. Y. Lee, T. Rendler, K. G. Lagoudakis, N. T. Son, E. Janzén, T. Ohshima, J. Wrachtrup, and J. Vučković, “Scalable Quantum Photonics with Single Color Centers in Silicon Carbide,” Nano Lett. 17, 1782-1786 (2017).
[2] D. M. Lukin, C. Dory, M. A. Guidry, K. Y. Yang, S. D. Mishra, R. Trivedi, M. Radulaski, S. Sun, D. Vercruysse, G. H. Ahn, and J. Vučković, “4H-silicon-carbide-on-insulator for integrated quantum and nonlinear photonics,” Nat. Photonics 14, 330-334 (2020).
[3] G. Calusine, A. Politi, and D. D. Awschalom, “Silicon carbide photonic crystal cavities with integrated color centers,” Appl. Phys. Lett. 105, 1-6 (2014).
[4] A. Lohrmann, T. J. Karle, V. K. Sewani, A. Laucht, M. Bosi, M. Negri, S. Castelletto, S. Prawer, J. C. McCallum, and B. C. Johnson, “Integration of Single-Photon Emitters into 3C—SiC Microdisk Resonators,” ACS Photonics 4, 462-468 (2017).
[5] J. Li and A. W. Poon, “Integrated Photon-pair Sources on a 3C—SiC-on-insulator Platform,” in Quantum 2.0 Conference and Exhibition, Technical Digest Series (Optica Publishing Group, 2022), paper QTu4B.6.
[6] J. Li and A. W. Poon, “Time-bin Entanglement Based on Integrated 3C—SiC-on-Insulator Photon-pair Sources,” presented at the Conference on Lasers and Electro-Optics, San Jose, United States, 7-12 May 2023.
[7] X. Guo, C. L. Zou, C. Schuck, H. Jung, R. Cheng, and H. X. Tang, “Parametric down-conversion photon-pair source on a nanophotonic chip,” Light Sci. Appl. 6, 1-8 (2017).
[8] G. T. Xue, Y. F. Niu, X. Liu, J. C. Duan, W. Chen, Y. Pan, K. Jia, X. Wang, H. Y. Liu, Y. Zhang, P. Xu, G. Zhao, X. Cai, Y. X. Gong, X. Hu, Z. Xie, and S. Zhu, “Ultrabright Multiplexed Energy-Time-Entangled Photon Generation from Lithium Niobate on Insulator Chip,” Phys. Rev. Appl. 15, 1 (2021).
[9] R. Cheng, C. Zou, X. Guo, S. Wang, X. Han, and H. X. Tang, “Broadband on-chip single-photon spectrometer,” Nat. Commun. 10, 4104 (2019).
[10] A. Al Sayem, R. Cheng, S. Wang, and H. X. Tang, “Lithium-niobate-on-insulator waveguide-integrated superconducting nanowire single-photon detectors,” Appl. Phys. Lett. 116, (2020).
[11] J. R. Ong, R. Kumar, and S. Mookherjea, “Ultra-High-Contrast and Tunable-Bandwidth Filter Using Cascaded High-Order Silicon Microring Filters,” IEEE Photonics Technol. Lett. 25, 1543-1546 (2013).
[12] N. C. Harris, D. Grassani, A. Simbula, M. Pant, M. Galli, T. Baehr-Jones, M. Hochberg, D. Englund, D. Bajoni, and C. Galland, “Integrated Source of Spectrally Filtered Correlated Photons for Large-Scale Quantum Photonic Systems,” Phys. Rev. X 4, 041047 (2014).
[13] M. Piekarek, D. Bonneau, S. Miki, T. Yamashita, M. Fujiwara, M. Sasaki, H. Terai, M. G. Tanner, C. M. Natarajan, R. H. Hadfield, J. L. O'Brien, and M. G. Thompson, “High-extinction ratio integrated photonic filters for silicon quantum photonics,” Opt. Lett. 42, 815 (2017).
[14] X. Nie, N. Turk, Y. Li, Z. Liu, and R. Baets, “High extinction ratio on-chip pump-rejection filter based on cascaded grating-assisted contra-directional couplers in silicon nitride rib waveguides,” Opt. Lett. 44, 2310 (2019).
[15] X. Guo, C.-L. Zou, and H. X. Tang, “70 dB long-pass filter on a nanophotonic chip,” Opt. Express 24, 21167 (2016).
[16] S. K. O'Leary, S. Zukotynski, J. M. Perz, and L. S. Sidhu, “Optical Absorption in Amorphous Silicon,” MRS Proc. 420, 545 (1996).
[17] M. Janai, D. D. Allred, D. C. Booth, and B. O. Seraphin, “Optical properties and structure of amorphous silicon films prepared by CVD,” Sol. Energy Mater. 1, 11-27 (1979).
[18] S. S. J. Ajayan and S. Kollem, “A Comprehensive Review on Thin Film Amorphous Silicon Solar Cells,” Silicon 8277-8293 (2022).
[19] M. D. Lukin, T. G. Tiecke, J. D. Thompson, N. P. De Leon, L. R. Liu, and V. Vuletic, “Nanophotonic quantum phase switch with a single atom,” Nature volume 508, pages 241-244 (2014).

What is claimed is:

1. An optical long-pass filter for long-pass filtering an incoming light beam to yield a filtered light beam, the incoming light beam including a desired light component and an undesired light component, the desired light component having one or more first constituent wavelengths, the undesired light component having one or more second constituent wavelengths, each of the one or more first constituent wavelengths being longer than each of the one or more second constituent wavelengths, the filter comprising:
a waveguide core for receiving the incoming light beam, propagating the desired and undesired light components inside the waveguide core, and outputting the filtered light beam; and
a selective-absorber layer deposited on the waveguide core, the selective-absorber layer being composed of an indirect-bandgap semiconductor material selected to have a bandgap energy greater than a maximum photon energy associated with the one or more first constituent wavelengths and less than a minimum photon energy associated with the one or more second constituent wavelengths such that when the desired and undesired light components interact with the selective-absorber layer during propagation inside the waveguide core, the undesired light component is attenuated while an optical power of the desired light component is retained.

2. The filter of claim 1, wherein the indirect-bandgap semiconductor material is selected to be amorphous silicon (α-Si) or polycrystalline silicon (poly-Si).

3. The filter of claim 2, wherein the selective-absorber layer has a thickness of less than or equal to 100 nm.

4. The filter of claim 1, wherein the waveguide core is realized as a strip waveguide.

5. The filter of claim 1, wherein the waveguide core is realized as a rib waveguide.

6. The filter of claim 1, wherein the waveguide core is composed of cubic silicon carbide (3C—SiC).

7. The filter of claim 1, wherein the waveguide core is composed of a material selected from silicon carbide (SiC), lithium niobate (LN) and aluminum nitride (AlN).

8. The filter of claim 1 further comprising:
an optical-insulator layer on which the waveguide core is positioned, wherein the optical-insulator layer provides a first reflective interface between the waveguide core and the optical-insulator layer to reflect the desired light component during propagation of the desired light component inside the waveguide core.

9. The filter of claim 8, wherein the optical-insulator layer is composed of silicon dioxide (SiO₂).

10. The filter of claim 8, wherein:
respective materials forming the optical-insulator layer and waveguide core are selected to allow total internal reflection to occur to the desired light component at the first reflective interface.

11. The filter of claim 8 further comprising:
a cladding deposited on at least a combined body consisting of the selective-absorber layer and the waveguide core, wherein the cladding is an optical-insulator cladding providing a second reflective interface between the waveguide core and the optical-insulator cladding to reflect the desired light component during propagation of the desired light component inside the waveguide core.

12. The filter of claim 11, wherein the cladding is composed of silicon dioxide (SiO₂).

13. The filter of claim 1, wherein the waveguide core is shaped to be straight.

14. The filter of claim 1, wherein the waveguide core is shaped to be bent.

15. The filter of claim 1, wherein:
the selective-absorber layer is shaped such that a non-filter section of the waveguide core is abruptly transited into a filter section thereof;
the filter section is a first longitudinal section of the waveguide core being entirely covered with the selective-absorber layer; and
the non-filter section is a second longitudinal section of the waveguide core being entirely not covered with any of the selective-absorber layer.

16. The filter of claim 1, wherein:
a longitudinal end of the selective-absorber layer has a tilted contour overlying a transition region between a non-filter section of the waveguide core and a filter section thereof such that the non-filter section is progressively transited into the filter section;
the filter section is a first longitudinal section of the waveguide core being entirely covered with the selective-absorber layer; and
the non-filter section is a second longitudinal section of the waveguide core being entirely not covered with any of the selective-absorber layer.

17. The filter of claim 1, wherein:
a longitudinal end of the selective-absorber layer has a one-stage taper contour overlying a transition region between a non-filter section of the waveguide core and a filter section thereof such that the non-filter section is progressively transited into the filter section;
the filter section is a first longitudinal section of the waveguide core being entirely covered with the selective-absorber layer; and
the non-filter section is a second longitudinal section of the waveguide core being entirely not covered with any of the selective-absorber layer.

18. The filter of claim 1, wherein:
a longitudinal end of the selective-absorber layer has a two-stage taper contour overlying a transition region between a non-filter section of the waveguide core and a filter section thereof such that the non-filter section is progressively transited into the filter section;
the filter section is a first longitudinal section of the waveguide core being entirely covered with the selective-absorber layer; and
the non-filter section is a second longitudinal section of the waveguide core being entirely not covered with any of the selective-absorber layer.

19. A light-conversion device for generating an output light beam from an input laser beam, the light-conversion device comprising:
one or more nonlinear quantum light sources collectively configured to perform a spontaneous parametric down-conversion of the input laser beam to nonlinearly generate a first light beam such that the first light beam includes a desired light component and an undesired light component, the desired light component having one or more first constituent wavelengths, the undesired light component having one or more second constituent wavelengths, each of the one or more first constituent wavelengths being longer than each of the one or more second constituent wavelengths; and
the optical long-pass filter of claim 1 for long-pass filtering the first light beam to yield the output light beam, wherein the first light beam is regarded as the incoming light beam, and the filtered light beam is regarded as the output light beam.

20. An optical system comprising:
the light-conversion device of claim 19; and
one or more photonic circuits for processing the output light beam.
